(19) United States
(12) Patent Application Publication
(10) Pub. No.: US 2017/0012233 A1
(43) Pub. Date: Jan. 12, 2017

(54) LIGHT EMITTING APPARATUS

(71) Applicant: PIONEER OLED LIGHTING DEVICES CORPORATION, Kawasaki-shi, Kanagawa (JP)

(72) Inventors: Daisuke MASUDA, Yonezawa-shi (JP); Masanobu AKAGI, Yonezawa-shi (JP); Yutaka SAITO, Yonezawa-shi (JP); Kazuhiro TAKEDA, Yonezawa-shi (JP)

(73) Assignee: PIONEER OLED LIGHTING DEVICES CORPORATION

(21) Appl. No.: 15/113,562

(22) PCT Filed: Jan. 29, 2014
(86) PCT No.: PCT/JP2014/052011

§ 371 Date: Jul. 22, 2016

(51) Int. Cl. H01L 51/52; H01L 51/56

(52) U.S. Cl. CPC H01L 51/524; H01L 51/5253; H01L 51/5206; H01L 51/5221; H01L 51/56; H01L 2251/5361

(57) ABSTRACT

A substrate (110) includes corners (112). An insulating layer (170) includes first openings (172). A light emitting element (102) overlaps the first opening (172), and includes an organic layer (130). At least one layer of the organic layer (130), for example, a hole injection layer, is a coated film, and other layers thereof are vapor-deposited films. Meanwhile, all the layers of the organic layer (130) may be coated films. At least one layer of the organic layer (130) which is a coated film is also located on the insulating layer (170), and includes a protruding region (132) protruding toward the corner (112) of the substrate (110).

### TECHNICAL FIELD

The present invention relates to a light emitting apparatus.

### BACKGROUND ART

The development of light emitting apparatuses using an organic EL element as a light source has been in progress. The organic EL element has a configuration in which an organic layer is interposed between a first electrode and a second electrode. An example of a method of forming the organic layer includes vapor deposition. On the other hand, in recent years, forming the organic layer by coating has been studied. For example, Patent Document 1 discloses forming a groove in the upper surface of a bank defining an organic layer. In Patent Document 1, an outer edge of the organic layer is defined by the groove.

### RELATED DOCUMENT

### Patent Document

[Patent Document 1] International Publication No. WO 2009/084209

### SUMMARY OF THE INVENTION

As described above, in recent years, forming an organic layer by ink jetting has been examined in order to improve the production efficiency of an organic EL element. In a case where ink jetting is used, the organic layer is formed by ink. Here, the ink is applied inside a groove formed in a structure such as a bank. However, in a case where the planar shape of the groove has corners, there is a tendency for the ink to overflow from the corners. For this reason, ink overflowing from the corners of a groove of a bank located on the outermost circumferential side may cover a portion of a substrate which is connected to a sealing member, which leads to the possibility of sealing properties being damaged.

The exemplified problem to be solved by the present invention is to suppress deterioration in sealing properties even in a case where a coating material overflows to the outside of a light emitting element.

According to the invention of claim 1, there is provided a light emitting apparatus including: a substrate including a corner; a structure formed on the substrate and including a plurality of first openings; and a light emitting element provided in a position overlapping the first opening and including a coated film, wherein the structure includes a second opening which is located between the corner of the substrate and a first opening closest to the corner.

### BRIEF DESCRIPTION OF THE DRAWINGS

The above and other objects, features and advantages will be made clearer from certain preferred embodiments described below, and the following accompanying drawings.

FIG. 1 is a plan view of a light emitting apparatus.

FIG. 2 is a diagram in which a sealing member is removed from FIG. 1.

FIG. 3 is a diagram in which a second electrode is removed from FIG. 2.

FIG. 4 is a diagram in which an organic layer and an insulating layer are removed from FIG. 3.

FIG. 5 is a diagram in which the organic layer is added to FIG. 3.

FIG. 6 are enlarged views of a region surrounded by a dotted line α of FIG. 3.

FIG. 7 is a cross-sectional view taken along line A-A of FIG. 3.

FIG. 8 is cross-sectional view taken along line B-B of FIG. 3.

FIG. 9 is a plan view illustrating a configuration of a light emitting apparatus according to Modification Example 1.

FIG. 10 is a plan view illustrating a configuration of a light emitting apparatus according to Modification Example 2.

FIG. 11 is a plan view illustrating a configuration of a light emitting apparatus according to Modification Example 3.

### DESCRIPTION OF EMBODIMENTS

Hereinafter, an embodiment of the present invention will be described with reference to the accompanying drawings. In all the drawings, like elements are referenced by like reference numerals and the descriptions thereof will not be repeated.

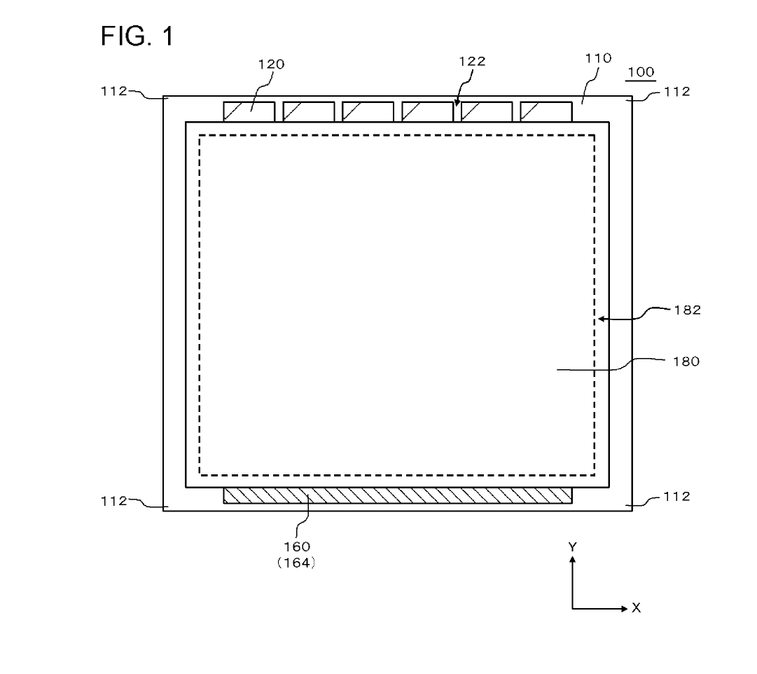

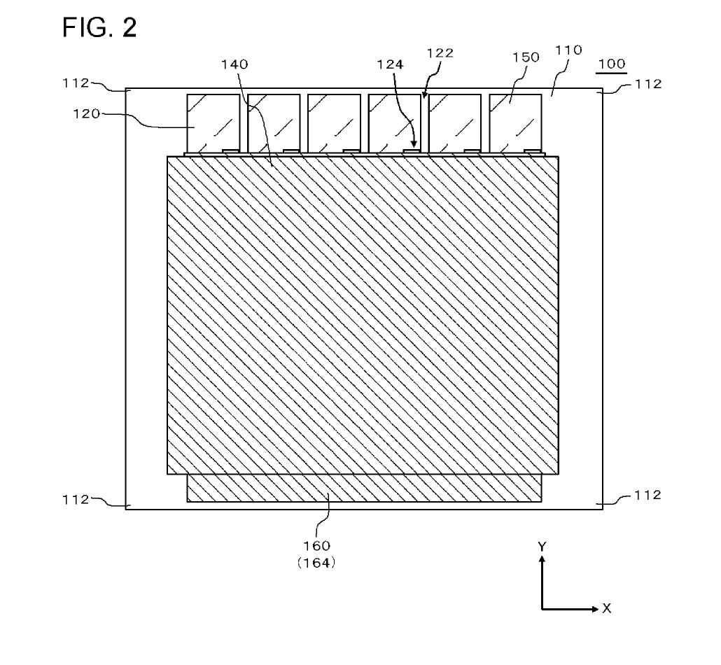

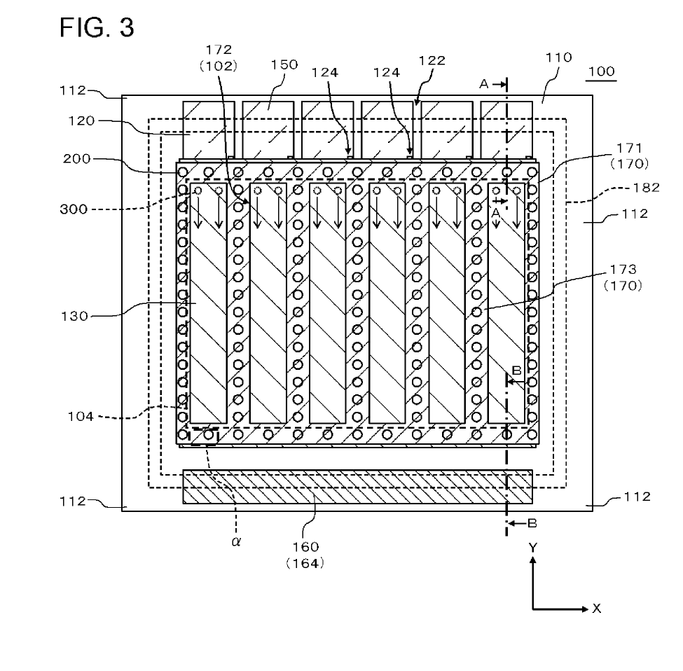

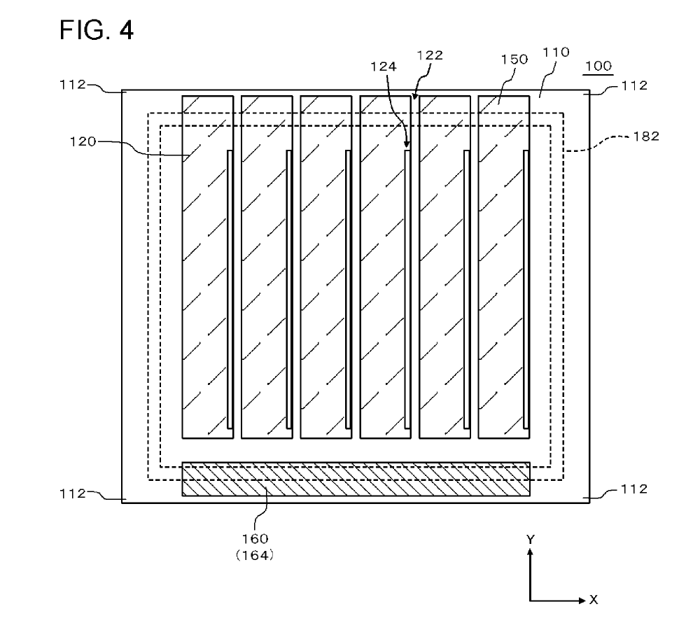

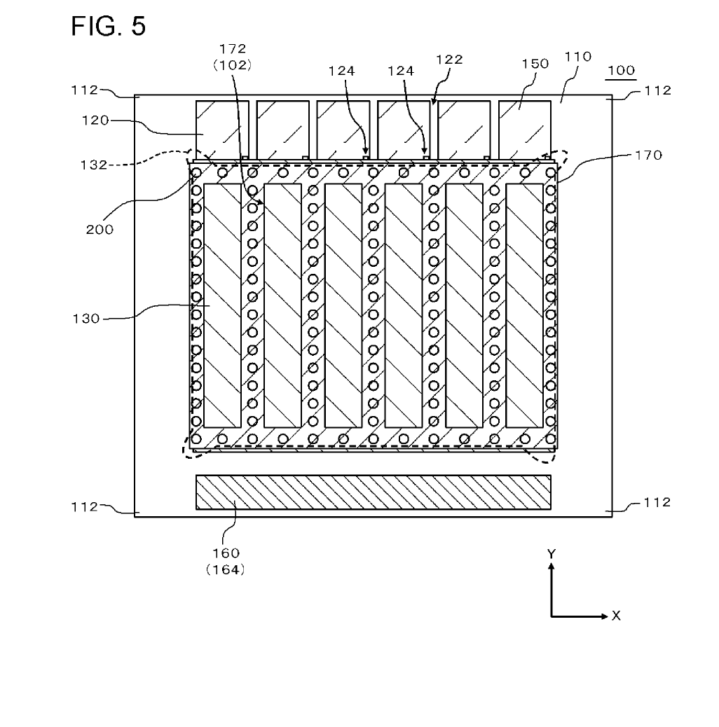

FIG. 1 is a plan view of a light emitting apparatus 100. FIG. 2 is a diagram in which a sealing member 180 is removed from FIG. 1, FIG. 3 is a diagram in which a second electrode 140 is removed from FIG. 2, and FIG. 4 is a diagram in which an organic layer 130 and an insulating layer 170 are removed from FIG. 3. FIG. 5 is a diagram in which the organic layer 130 is added to FIG. 3.

The light emitting apparatus 100 according to the present embodiment includes a substrate 110, an insulating layer 170 (structure), and light emitting elements 102 (for example, organic EL elements). The substrate 110 has corners 112. The insulating layer 170 has first openings 172. The light emitting element 102 overlaps the first opening 172, and has an organic layer 130. At least one layer of the organic layer 130, for example, a hole injection layer, is a coated film, and other layers are vapor-deposited films. Meanwhile, all the layers of the organic layer 130 may be coated films. As shown in FIG. 5, at least one layer of the organic layer 130 which is a coated film is also located on the insulating layer 170, and includes protruding regions 132 protruding toward the corners 112 of the substrate 110. Meanwhile, the planar shape of the first opening 172 is a shape having corners, for example, a rectangular shape. A straight line that links the corners 112 is not overlapped with a first terminal 150 and a second terminal 160 described later. The planar shape of the first opening 172 may be a shape in which two sides of a rectangle facing each other is formed in a circular arc (for example, semicircle), or may be a multi-angular shape. The shape of the corner of the first opening 172 is not required to have a precise angle, and may be a curve such as a circular arc.

In addition, the light emitting apparatus 100 includes a light-emitting portion 104. The light-emitting portion 104 includes the light emitting element 102. The light-emitting portion 104 is sealed by the sealing member 180. The light emitting apparatus 100 includes a first terminal 150 for each of a plurality of light emitting elements 102. A sealed region 182 of the substrate 110 which shields a space sealed by the sealing member 180 from the outside surrounds the light-emitting portion 104 and the structure. This sealed region 182 is a connecting portion in which the substrate 110 and the sealing member 180 are connected to each other. Hereinafter, a detailed description will be given.

The light emitting apparatus 100 is polygonal, for example, rectangular, and includes the plurality of light emitting elements 102, the first terminal 150, and the second terminal 160. The first terminal 150 and the second terminal 160 are provided in order to supply power to the light emitting elements 102. For this reason, a connecting member (for example, a bonding wire or a lead member) for supplying power to the light emitting apparatus 100 is connected to the first terminal 150 and the second terminal 160.

The light emitting element 102 has a configuration in which the first electrode 120, the organic layer 130, and the second electrode 140 are laminated on the substrate 110. In the example shown in the drawings, the first electrode 120, the organic layer 130, and the second electrode 140 are laminated on the substrate 110 in this order. However, the first electrode 120 and the second electrode 140 may be reversed. In the example shown in the drawings, multiple types of light emitting elements 102 that emit light colors (for example red, green, and blue) different from each other are repeatedly disposed on the substrate 110. Thereby, the light emitting apparatus 100 is configured as an illumination device capable of dimming light.

The substrate 110 is a transparent substrate such as, for example, a glass substrate or a resin substrate. The substrate 110 may have flexibility. In this case, the thickness of the substrate 110 is, for example, equal to or greater than 10 μm and equal to or less than 10,000 μm. Even in this case, the substrate 110 may be formed of any of an inorganic material and an organic material. The substrate 110 is polygonal, for example, rectangular. The vicinity of a vertex of the polygon is configured as the corner 112.

The organic layer 130 includes a light emitting layer. The organic layer 130 has, for example, a configuration in which a hole transport layer, a light emitting layer, and an electron transport layer are laminated in this order. A hole injection layer may be formed between the first electrode 120 and the hole transport layer. In addition, an electron injection layer may be formed between the electron transport layer and the second electrode 140. At least one layer of the organic layer 130, for example, the hole injection layer, is formed by coating such as by ink jetting. The remaining layers of the organic layer 130 are formed by vapor deposition. Meanwhile, at least the light emitting layer of the organic layer 130 differs depending on the type of light emitting element 102.

The width of the light-emitting portion 104 is larger than the width of a nozzle head for ink jetting. For this reason, the organic layer 130 is coated onto the entire light-emitting portion 104 by scanning the nozzle head multiple times in a second direction (Y direction in the drawing). Here, a region (coating region) of the organic layer 130 that is coated by a single scanning of the nozzle head overlaps, in an X direction in the drawing, a coating region coated immediately prior thereto. For this reason, a thick-film region may be formed in the organic layer 130. This thick-film region extends in a direction (second direction: Y direction in FIGS. 1 to 4) in which the nozzle head is scanned. Meanwhile, the organic layer 130 may have a region thinner than other regions formed therein instead of the thick-film region.

The first electrode 120 functions as, for example, an anode of the light emitting element 102, and the second electrode 140 functions as, for example, a cathode of the light emitting element 102. Both the first electrode 120 and the second electrode 140 are formed by vapor deposition or sputtering. One of the first electrode 120 and the second electrode 140 (first electrode 120 in the example shown in the drawing) is a transparent electrode having optical transparency. Light emitted by the light emitting element 102 is emitted to the outside through an electrode (first electrode 120 in the example shown in the drawing) of the first electrode 120 and the second electrode 140 which serves as a transparent electrode. The material of the transparent electrode contains, for example, an inorganic material such as an indium tin oxide (ITO) or an indium zinc oxide (IZO), or a conductive polymer such as a polythiophene derivative.

In addition, the other electrode of the first electrode 120 and the second electrode 140 (second electrode 140 in the example shown in the drawing) includes a metal layer which is formed of a metal selected from a first group consisting of Au, Ag, Pt, Sn, Zn, and In, or an alloy of metals selected from this first group.

More specifically, as shown in FIGS. 2, 3, and 4, the first electrodes 120 are configured to be separated from each other with respect to each of the plurality of light emitting elements 102. The plurality of first electrodes 120 are respectively connected to the first terminals 150 different from each other. The first electrodes 120 are continuously formed from a region of the substrate 110 which serves as the light-emitting portion 104 to the first terminal 150. In the example shown in the drawings, the substrate 110 is rectangular, and the first terminal 150 is provided near the end of the first electrode 120, that is, near one side of the substrate 110.

In addition, as shown in FIG. 2, the second electrodes 140 of the plurality of light emitting elements 102 are continuous with each other. In other words, the second electrodes 140 are formed as an electrode common to the plurality of light emitting elements 102. Specifically, the second electrode 140 is formed on the organic layer 130 and the insulating layer 170, and is connected to the second terminal 160. In the example shown in the drawings, the second terminal 160 is formed along the other side (a side facing the one side) of the substrate 110.

In the examples shown in FIGS. 1 to 4, a plurality of first terminals 150 are disposed along a first direction, and the second terminal 160 is disposed along a second direction. Both the first terminal 150 and the second terminal 160 are located between the corners 112. The insulating layer 170 and the light-emitting portion 104 are located between the first terminal 150 and the second terminal 160. In this manner, since terminals are not required to be provided near the other two sides of the substrate, it is possible to reduce the size of a region of a frame (non-light-emitting portion). Thereby, it is possible to reduce the width of the frame which is formed when a plurality of panels are disposed so as to be adjacent to each other.

The first terminal 150 is formed of a material constituting the first electrode 120.

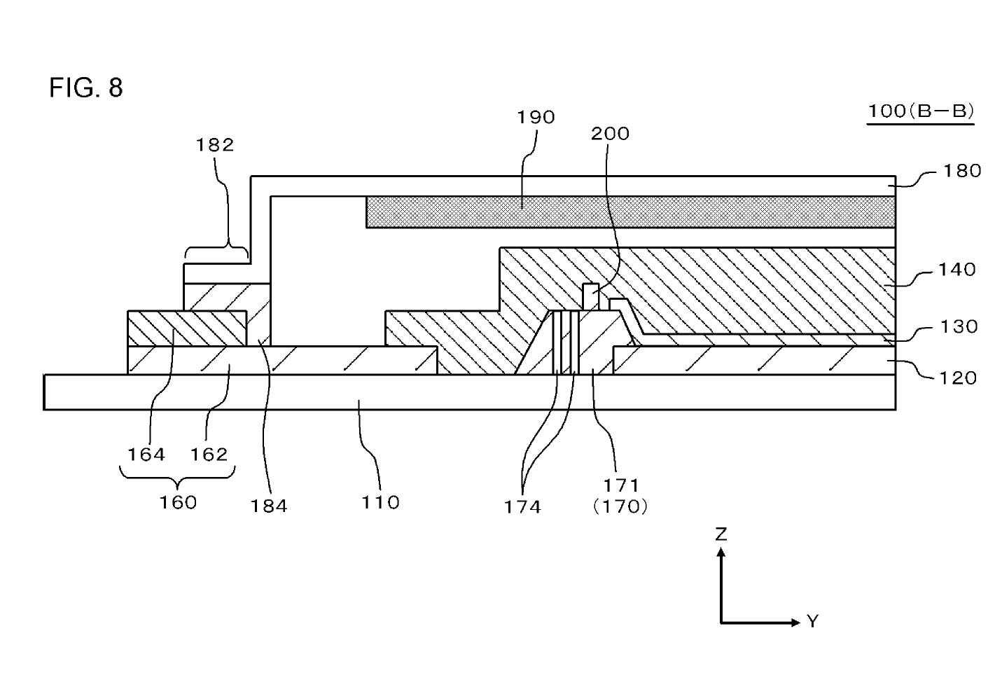

On the other hand, as described later with reference to FIG. 8, the second terminal 160 has a configuration in which a second layer 164 is laminated on a first layer 162. The first layer 162 is formed of the same material as that of the first electrode 120. However, the first layer 162 is separated from the first electrode 120. The second layer 164 is formed of a material having a lower resistance than that of the first layer 162, for example, a metal film such as a laminated film of Mo/Al/Mo. Meanwhile, the same layer as the second layer 164 may also be formed on the first terminal 150.

In addition, as shown in FIGS. 1 and 4, the plurality of light emitting elements 102 are sealed by the sealing member 180. The sealing member 180 has a shape in which the entire circumference of the edge portion of a metal foil or a metal plate (for example, Al foil or Al plate) having the same polygonal shape as that of the substrate 110 is pushed down. The edge portion is fixed to the substrate 110 with an adhesive material, a sticking material or the like. In this manner, the sealed region 182 is formed on the entire circumference of the edge portion of the sealing member 180. The sealed region 182 is a region of the substrate 110 shielding a space sealed by the sealing member 180 from the outside. The sealed region 182 has a shape following along each side of the polygon having the same number of corners as that of the substrate 110, and surrounds the light-emitting portion 104 and the organic layer 130 as shown in FIG. 3. However, the sealing member 180 may be formed of glass.

A portion of the first terminal 150 and a portion of the second terminal 160 are located outside the sealing member 180. A conductive member is connected to a portion of the first terminal 150 located outside the sealing member 180 and a portion of the second terminal 160 located outside the sealing member 180. This conductive member is, for example, a lead frame or a bonding wire, and connects the first terminal 150 (or second terminal 160) to a circuit substrate or the like.

An auxiliary electrode 124 comes into contact with the first electrode 120. In the example shown in the drawings, the auxiliary electrode 124 is provided on the surface of the first electrode 120 opposite to the substrate 110, and is located within the light-emitting portion 104. The auxiliary electrode 124 is provided to each of the plurality of light emitting elements 102, and is located near the edge of the first electrode 120 in a direction in which the first electrode 120 extends. The auxiliary electrode 124 is formed of a material (metal such as, for example, Ag or Al) having a lower resistance value than that of the first electrode 120. The auxiliary electrode 124 is formed, and thus it is possible to prevent a voltage drop from occurring in the in-plane of the first electrode 120. Thereby, it is possible to prevent a distribution from occurring in the luminance of the light emitting apparatus 100. The auxiliary electrode 124 is formed by, for example, sputtering, but may be formed by coating.

As shown in FIG. 3, the insulating layer 170 is formed in a gap between the first electrodes 120 and on the auxiliary electrode 124. The insulating layer 170 is formed of a photosensitive resin such as, for example, polyimide. A plurality of first openings 172 are provided in the insulating layer 170. The first opening 172 extends in parallel with the first electrode 120 and the auxiliary electrode 124. However, the first opening 172 does not overlap the auxiliary electrode 124 and the gap 122 between the first electrodes 120. For this reason, the auxiliary electrode 124 is covered with the insulating layer 170, and a portion of the gap 122 which is located inside the light-emitting portion 104 is also covered with the insulating layer 170. In addition, the aforementioned organic layer 130 is formed inside the first opening 172. By applying a voltage or a current between the first electrode 120 and the second electrode 140, the organic layer 130 located within the first opening 172 emits light. In other words, the light emitting element 102 is formed in each of the first openings 172. The light-emitting portion 104 is partitioned into the plurality of light emitting elements 102 by the insulating layer 170. The light emitting element 102 are aligned in the first direction (X direction in the drawing). Meanwhile, only one nozzle 300 for coating the organic layer 130 may be disposed in one first opening 172, and a plurality of nozzles may be disposed therein. Meanwhile, a portion of the auxiliary electrode 124 may protrude to the first opening 172 in the width direction of the auxiliary electrode 124, and all the auxiliary electrodes 124 may be covered with the insulating layer 170.

In addition, columnar members 200 are provided on the insulating layer 170. The columnar member 200 is provided in order to prevent a vapor deposition mask (for example, mask used when forming a vapor-deposited film serving as the organic layer 130) from coming into contact with the insulating layer 170 or the like. In the example shown in FIG. 3, the columnar member 200 has a cylindrical shape, and a plurality of columnar members are provided so as to be separated from each other. The columnar members 200 are respectively provided in a portion of the insulating layer 170 surrounding the light-emitting portion 104 and a portion thereof covering the gap 122 between the first electrodes 120.

The insulating layer 170 surrounds the light emitting element 102. Specifically, the insulating layer 170 includes an outer circumferential portion 171 touching the outer frame of the light-emitting portion 104 and a wall portion 173 on the insulating layer 170 located between the adjacent light emitting elements 102. The outer circumferential portion 171 has a shape following along the rectangular edge, and may be formed to be thicker than the wall portion 173.

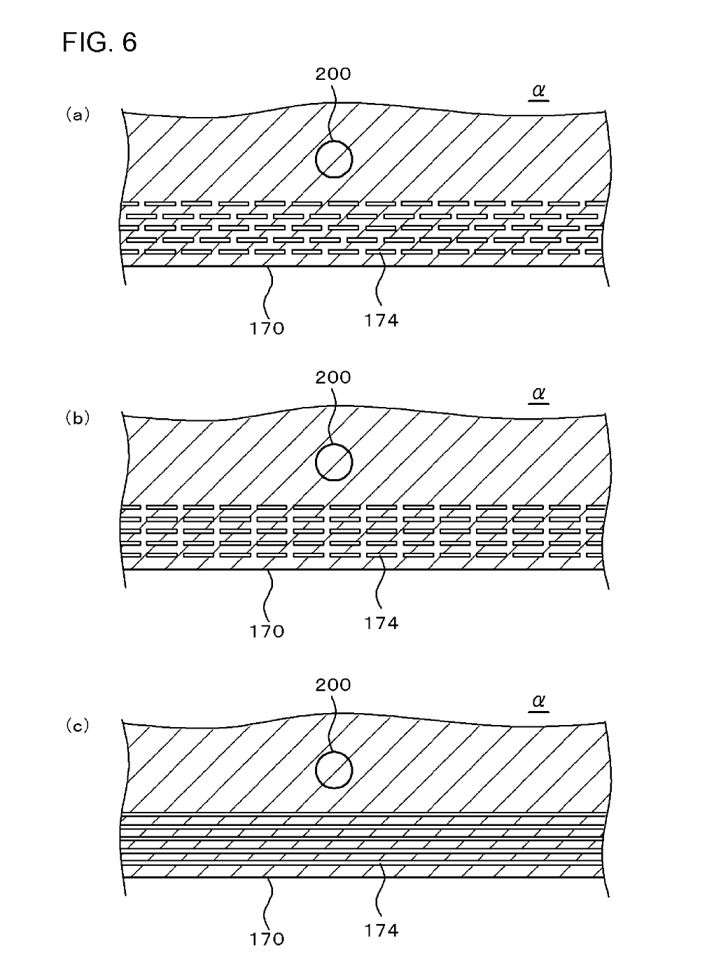

FIG. 6 are enlarged views of a region α of FIG. 3. As shown in FIG. 6, a plurality of second openings 174 are provided on the outer circumferential portion 171. The plurality of second openings 174 are disposed in a portion of the insulating layer between the first terminal 150 and the second terminal 160, for example, a portion between the plurality of first openings 172 (that is, light-emitting portions 104) and the second terminal 160. However, the plurality of second openings 174 may also be provided in other portions (for example, between the first terminal 150 and the plurality of first openings 172). Meanwhile, it can be said that the second opening 174 is adjacent to the first opening 172.

In the example shown in FIG. 6(a), the second openings 174 are arrayed so as to form a plurality of rows. The second openings 174 belonging to a certain row and the second openings 174 belonging to a row located outside the one row are alternately disposed with each other. That is, the plurality of second openings 174 are arranged in a zigzag. Particularly, the plurality of second openings 174 are disposed so that the corners of the second openings 174 belonging to a certain row and the centers the second openings 174 belonging to a row located outside or inside the one row overlap each other. Thereby, it is possible to prevent a coating material from further spreading from the first opening 172 toward the second terminal 160 than in an example shown in FIG. 6(b) described later. In addition, the plurality of second openings 174 are disposed in a circumferential direction, and thus it is possible to prevent a coating material from further spreading in the circumferential direction compared to an example shown in FIG. 6(c) described later.

In the example shown in FIG. 6(b), the second openings 174 are disposed at equal intervals. The plurality of second openings 174 are disposed in the circumferential direction, and thus it is possible to prevent a coating material from further spreading in the circumferential direction than in the example shown in FIG. 6(c) described later.

In the example shown in FIG. 6(c), the second openings 174 extend linearly, and the plurality of second openings are disposed at equal intervals. Thereby, it is possible to prevent a coating material from further spreading from the first opening 172 toward the second terminal 160 compared to the example shown in FIG. 6(b).

In the examples shown in FIGS. 6(a) and 6(b), the second opening 174 has an elongated shape (for example, rectangular shape), and its long axis is directed in the extending direction of the outer circumferential portion 171. The interval between two second openings 174 belonging to the same row (that is, the width of the remaining portion of the insulating layer 170) is smaller than the length of the long axis of the second opening 174. Meanwhile, in a case where a portion of the region α is located at the corner of the outer circumferential portion 171, the second opening 174 may be formed in an L-shape. This shape will be described later.

In addition, when seen in the width direction of the outer circumferential portion 171, the second openings 174 are not provided on the entirety of the outer circumferential portion 171, and are formed in only a region which is located closer to the side opposite to the first opening 172 than the center of the second openings 174. This can allow a coating material for forming the organic layer 130 to be coated on a portion of the outer circumferential portion 171 which is located near the first opening 172. Thereby, when forming the organic layer 130 by drying the coating material, even if the coating material is contracted, an occurrence of a portion not having the organic layer 130 formed therein in a region inside the first opening 172 can be prevented. Meanwhile, if a portion not having the organic layer 130 formed therein occurs in the region inside the first opening 172, a non-light-emitting portion is formed in a portion overlapping the first opening 172, which leads to a deterioration in the quality of the light emitting apparatus 100.

Since the second opening 174 is provided on the outer circumferential portion 171, the coating material for forming the organic layer 130 is not likely to flow outside the outer circumferential portion 171 by a pinning effect generated at the edge of the second opening 174. That is, an annular inclined surface is formed generated by forming the second opening 174. The pinning effect is exhibited with respect to the coating material by this inclined surface. The angle of the inclined surface is an acute angle (forward tapered shape) with respect to the substrate 110. As the angle of the inclined surface with respect to the substrate 110 becomes larger (called an obtuse angle or an inverted tapered shape), the pinning effect increases, and the coating material is not likely to infiltrate into the second opening 174. Particularly, in the example shown in FIG. 6, several rows of second openings 174 are disposed. Therefore, it is possible to prevent the coating material from spreading in both the direction in which the outer circumferential portion 171 extends and the width direction of the outer circumferential portion 171, on the upper surface of the outer circumferential portion 171. The coating material overflowing from the first opening 172 flows from the corner of the insulating layer 170 toward the corner 112 of the substrate 110, forming the protruding region 132.

Meanwhile, the expression of the pinning effect described above is generated likewise in the first opening 172.

Meanwhile, the second opening 174 is not required to penetrate the insulating layer 170, and may be a concave portion (meaning an insulating layer is present within the second opening 174, which is thinner than a portion of the insulating layer 170 other than the second opening 174).

In addition, the angle of the inclined surface with respect to the substrate 110 in the corners of the first opening 172 and the second opening 174 may be smaller than the angle of the inclined surface with respect to the substrate 110 in portions other than the corners. For this reason, the coating material is more likely to spread in the corners of the first opening 172 and the second opening 174 than in other portions.

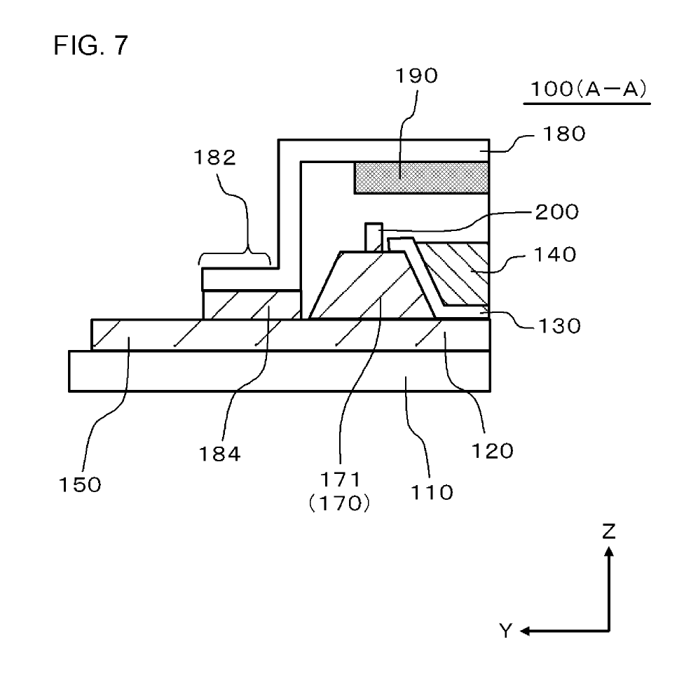

FIG. 7 is a cross-sectional view taken along line A-A of FIG. 3, and FIG. 8 is a cross-sectional view taken along line B-B of FIG. 3. As described above, the end of the first electrode 120 serves as the first terminal 150. In addition, the second terminal 160 has a configuration in which the second layer 164 is laminated on the first layer 162. The second layer 164 is formed in, for example, the same process as that in which the auxiliary electrode 124 is formed. In this case, the second layer 164 is formed of the same material as that of the auxiliary electrode 124.

In addition, the organic layer 130 is also formed on the lateral surface and upper surface of the wall portion 173 of the insulating layer 170. Further, the organic layer 130 is air-tightly sealed by the sealing member 180. A moisture absorbent 190 is provided in a space (hereinafter, referred to as a sealed space) sealed between the sealing member 180 and the substrate 110. In the example shown in FIGS. 7 and 8, the moisture absorbent 190 is fixed to the surface of the sealing member 180 facing the substrate 110.

The edge portion of the sealing member 180 is fixed directly to the substrate 110, or through a resin layer 184 formed on the substrate 110. Thereby, the sealed region 182 is formed. The resin layer 184 is formed of, for example, a resin (resin sheet) formed in a sheet shape in advance. The resin layer 184 is formed in an annular shape along the edge portion of the sealing member 180. In the example shown in FIGS. 7 and 8, the resin layer 184 is located between the sealed region 182 (connecting portion between the substrate 110 and the sealing member 180) and the first terminal 150, and between the sealed region 182 and the second terminal 160, but is not provided in a portion overlapping the light-emitting portion 104.

The second opening 174 is located between the sealed region 182 and the first opening 172 out of the plurality of first openings 172 which is closest to the sealed region 182. In addition, the second opening 174 is located in the vicinity of the corner 112 of the substrate 110. By disposing the second opening 174 in this manner, it is possible to suppress spreading of the coating material overflowing from the first opening 172 to the sealed region 182. Particularly, the coating material has a greater tendency to overflow from the corner of the first opening 172 than from portions other than the corner of the first opening 172. It is considered that this is because, supposedly, the coating material prevented from overflowing from a portion of the first opening 172 other than the corner is collected in the corner of the first opening 172, and as a result, the coating material overflows from the corner of the first opening 172. In addition, regarding the side surface of the insulating layer 170 in the first opening 172, in a case where the angle of the side surface in the corner of the first opening 172 with respect to the substrate 110 is smaller than the angles at the side surfaces in other portions of the first opening 172, it is considered that the coating material has a greater tendency to overflow from the corner.

Thus, a coated film for forming the organic layer 130 may be formed in a shape in which the outer circumferential portion of a portion facing the corner of the substrate 110 comes closer to the edge portion of the substrate 110, that is, a shape protruding toward the sealed region 182 (protruding region 132 described later), compared to the outer circumferential portion of a portion facing each side of the substrate 110. However, the aforementioned second openings 174 are provided between the first opening 172 and the sealed region 182, and thus it is possible to prevent the protruding region 132 of the coated film from extending up to the sealed region 182 (to prevent the coating material from overflowing up to the sealed region 182). As a result, it is possible to prevent the sealed region 182 from being covered with the coated film.

In addition, in a case where the coated film (organic layer 130) is formed only within the first opening 172, the thickness of the coated film may not become sufficiently uniform due to a “coffee stain effect” phenomenon. Consequently, in order to improve the uniformity of the thickness of the coated film within the first opening 172, the coated film is formed on the outer circumferential portion 171, the first opening 172, and the wall portion 173 of the insulating layer 170. In this case, a portion of the coated film located on the outer circumferential portion 171 of the insulating layer 170 becomes thicker or thinner than the coated film formed within the first opening 172, but the thickness of the coated film located with the first opening 172 can be made uniform.

Next, a method of manufacturing the light emitting apparatus 100 according to the present embodiment will be described. First, a conductive film serving as the first electrode 120 is formed on the substrate 110 by, for example, vapor deposition or sputtering. Next, a resist pattern is formed on this conductive film, and the conductive film is etched using this resist pattern as a mask. Thereby, the first electrode 120 (including the first terminal 150) and the first layer 162 of the second terminal 160 are formed. Thereafter, the resist pattern is removed.

Next, a conductive film serving as the auxiliary electrode 124 is formed on the substrate 110. Next, a resist pattern is formed on this conductive film, and the conductive film is etched using this resist pattern as a mask. Thereby, the auxiliary electrode 124 and the second layer 164 of the second terminal 160 are formed. Thereafter, the resist pattern is removed.

Next, an insulating photosensitive material serving as the insulating layer 170 is formed on the first electrode 120 by, for example, coating. Next, this photosensitive material is exposed and developed. Thereby, the insulating layer 170, the first opening 172, and the second opening 174 are formed. Next, an insulating photosensitive material serving as the columnar member 200 is formed on the insulating layer 170 by, for example, by coating. Next, this photosensitive material is exposed and developed. Thereby, the columnar member 200 is formed.

Next, the organic layer 130 is formed within the first opening 172 by ink jetting. In this case, the organic layer 130 is coated separately for each type of light emitting element 102. When the organic layer 130 is formed by ink jetting, the nozzle head having the nozzle 300 is scanned. The start position of the nozzle 300 in this case is on the outer circumferential portion 171 of the insulating layer 170. In addition, a coating material is not applied directly to the side surface and upper surface of the wall portion 173. However, the coating material applied to the first opening 172 creeps up the side surface of the wall portion 173 by capillary action, covering the upper surface of the wall portion 173.

Next, the second electrode 140 is formed on the organic layer 130 and the insulating layer 170 by vapor deposition or sputtering. Thereafter, the sealing member 180 is attached onto the substrate 110.

As described above, according to the present embodiment, the coating material for forming the organic layer 130 is also located on the outer circumferential portion 171 and the wall portion 173 of the insulating layer 170. Therefore, even in a case the coating material is contracted when the coating material is dried and the organic layer 130 is formed, it is possible to prevent a portion not having the organic layer 130 formed therein from occurring in a region located inside the first opening 172. Here, there is a possibility of the coating material overflowing up to the external side of the outer circumferential portion 171, but the coating material overflows toward the corner 112 of the substrate 110. Thereby, it is possible to prevent the overflowing coating material from covering the first terminal 150 and the second terminal 160.

In addition, since the second opening 174 is formed on the outer circumferential portion 171, it is possible to prevent the coating material from overflowing outside the outer circumferential portion 171 by a pinning effect generated by the second opening 174. In addition, even in a case where the coating material overflows outside the outer circumferential portion 171, this coating material spreads toward the corner 112 of the substrate 110, forming the protruding region 132. Therefore, it is possible to prevent the protruding region 132 from overlapping the first terminal 150 and the second terminal 160.

### MODIFICATION EXAMPLE 1

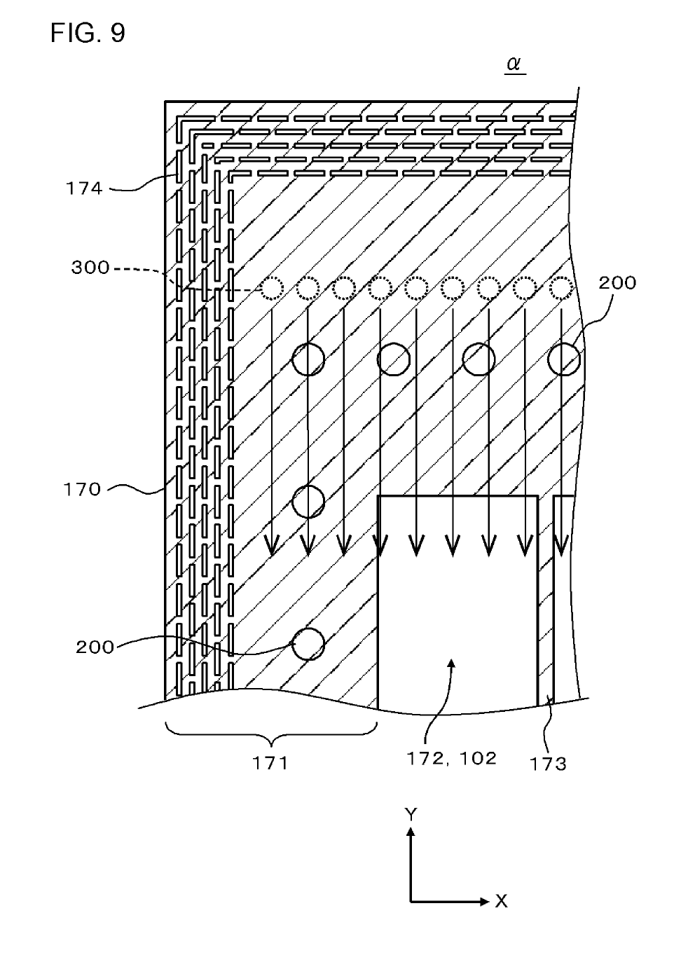

FIG. 9 is a diagram illustrating a configuration of a light emitting apparatus 100 according to a modification example, and is an enlarged view of the corner of the insulating layer 170. Also in the present modification example, the insulating layer 170 surrounds the light emitting element 102. Specifically, the insulating layer 170 includes the outer circumferential portion 171 touching the outer frame of the light-emitting portion 104, and the wall portion 173 for partitioning the adjacent light emitting elements 102. The outer circumferential portion 171 has a shape following along the edges of the rectangle, and is thicker than the wall portion 173. Particularly, a portion of the outer circumferential portion 171 facing the first terminal 150 becomes thicker than a portion of the outer circumferential portion 171 facing the second terminal 160. A plurality of second openings 174 are provided in the wall portion 173. The plurality of second openings 174 are disposed throughout the entirety of the outer circumferential portion 171 in a circumferential direction so as to surround a plurality of first openings 172 (that is, light-emitting portion 104). Specifically, the second openings 174 are shaped as shown in FIG. 6(a).

In addition, when seen in the width direction of the outer circumferential portion 171, the second openings 174 are not provided on the entirety of the outer circumferential portion 171, and are formed in only a region which is located closer to the side opposite to the first opening 172 than the center of the second openings 174. This can allow a coating material for forming the organic layer 130 to be coated on a portion of the outer circumferential portion 171 near the first opening 172. Thereby, even in a case the coating material is contracted when the coating material is dried and the organic layer 130 is formed, it is possible to prevent a portion not having the organic layer 130 formed therein from occurring in a region located inside the first opening 172. Meanwhile, if a portion not having the organic layer 130 formed therein occurs in the region located inside the first opening 172, a non-light-emitting portion is formed in a portion overlapping the first opening 172, which leads to a deterioration in the quality of the light emitting apparatus 100. Meanwhile, in the embodiment, the second opening 174 may be disposed in the manner as described above.

Since the second openings 174 are provided on the outer circumferential portion 171, the coating material for forming the organic layer 130 is not likely to flow outside the outer circumferential portion 171 by a pinning effect generated at the edge of the second openings 174. That is, an annular inclined surface generated by forming the second openings 174 is formed. The pinning effect is obtained with respect to the coating material by this inclined surface. The angle of the inclined surface is an acute angle (forward tapered shape) with respect to the substrate 110. As the angle of the inclined surface with respect to the substrate 110 becomes larger (called an obtuse angle or an inverted tapered shape), the pinning effect increases, and the coating material is not likely to infiltrate into the second openings 174. Particularly, in the example shown in FIG. 9, the second openings 174 are disposed in a zigzag. Therefore, it is possible to prevent the coating material from spreading in both the direction in which the outer circumferential portion 171 extends and the width direction of the outer circumferential portion 171, on the upper surface of the outer circumferential portion 171. The coating material protruding from the first opening 172 overflows from the corner of the insulating layer 170 toward the corner 112 of the substrate 110, forming the protruding region 132.

### MODIFICATION EXAMPLE 2

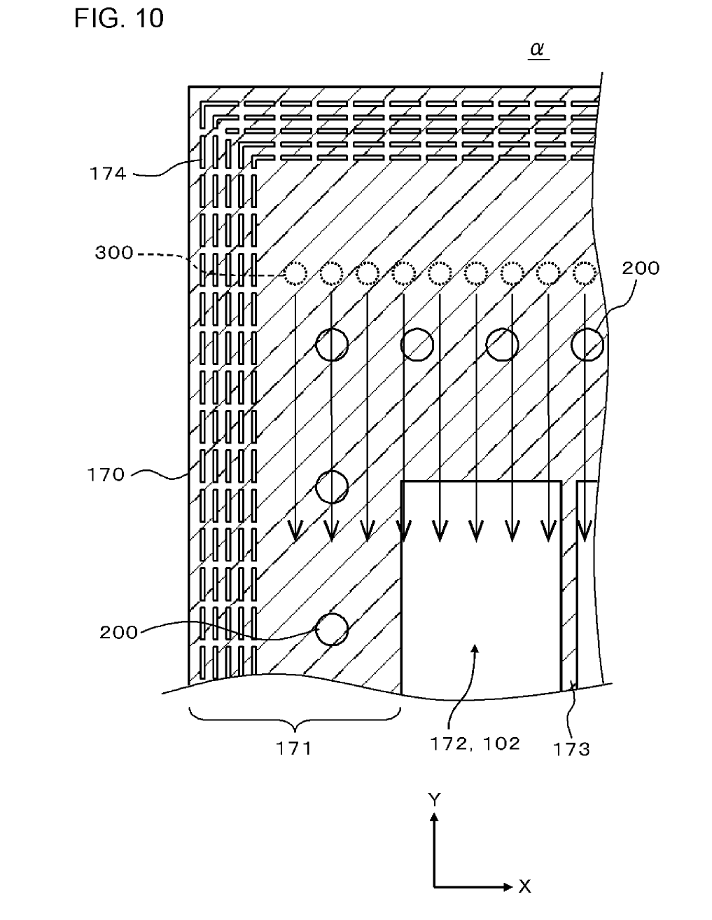

FIG. 10 is a plan view illustrating a configuration of a light emitting apparatus 100 according to Modification Example 2. The light emitting apparatus 100 according to the present modification example has the same configuration as that of the light emitting apparatus 100 according to Modification Example 1, except that the layout of the second openings 174 is the same as that in the example shown in FIG. 6(b).

### MODIFICATION EXAMPLE 3

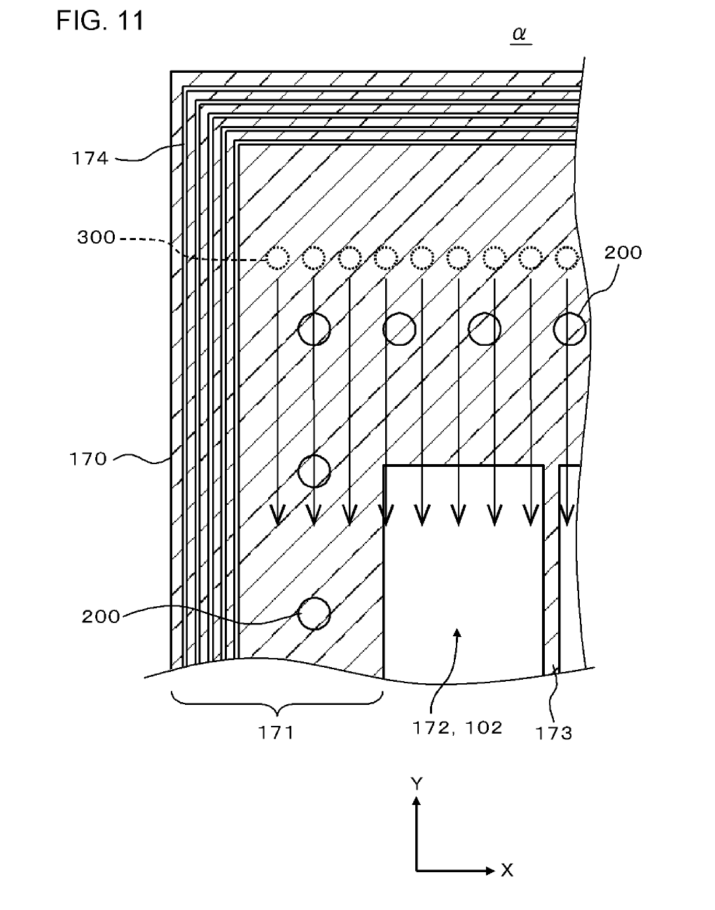

FIG. 11 is a plan view illustrating a configuration of a light emitting apparatus 100 according to Modification Example 3. The light emitting apparatus 100 according to the present modification example has the same configuration as that of the light emitting apparatus 100 according to Modification Example 1, except that the layout of the second openings 174 is the same as that in the example shown in FIG. 6(c).

As described above, although the embodiment and examples have been set forth with reference to the accompanying drawings, they are merely illustrative of the present invention, and various configurations other than those stated above can be adopted.

1. A light emitting apparatus comprising:
a substrate including corners;
a structure formed on the substrate and including a plurality of first openings; and
a light emitting element provided in a position overlapping the first opening and including a coated film,
wherein the structure includes a second opening which is located between the corner of the substrate and a first opening closest to the corner.

2. The light emitting apparatus according to claim 1,
wherein the substrate is polygonal,
further comprising a plurality of terminals which are located between the corners of the substrate, and
the terminal is connected to the light emitting element.

3. The light emitting apparatus according to claim 2, further comprising a sealing member that seals the light emitting element,
wherein the coated film is located further inside than a connecting portion between the substrate and the sealing member.

4. The light emitting apparatus according to claim 3, wherein the terminal is located outside the connecting portion.

5. The light emitting apparatus according to claim 4, wherein the coated film is located over the structure and includes a protruding region facing the corner.

6. The light emitting apparatus according to claim 5, wherein the protruding region is located further inside than the connecting portion.

7. The light emitting apparatus according to claim 6,
wherein the structure includes a plurality of the second openings, and
the second opening out of the plurality of second openings which is located on the first opening side in a direction along an edge of the substrate is located at a position different from that of the second opening located on the edge side of the substrate.

8. The light emitting apparatus according to claim 6, wherein the structure includes a plurality of the second openings, and
the second openings extend linearly.

9. The light emitting apparatus according to claim 6, wherein the plurality of terminals include
a first terminal which is electrically connected to a first electrode of the light emitting element, and
a second terminal which is electrically connected to a second electrode of the light emitting element,
the first terminal and the second terminal are located at positions facing each other with the first opening interposed therebetween, and
the second opening is formed in a portion of the structure which is located between the first terminal and the second terminal.

10. The light emitting apparatus according to claim 9, wherein the light emitting element is located in the first opening adjacent to the second opening.

11. The light emitting apparatus according to claim 10, wherein the coated film covers the structure which is located further inside than the second opening, and
the coated film which is located over the structure is thicker than the coated film which is located within the first opening.

12. The light emitting apparatus according to claim 10, wherein the coated film covers the structure which is located further inside than the second opening, and
the coated film which is located over the structure is thinner than the coated film which is located within the first opening.
